(19) United States
(12) Patent Application Publication
(10) Pub. No.: US 2026/0047055 A1
(43) Pub. Date: Feb. 12, 2026

(54) SHIELDING STRUCTURE FOR ELECTROMAGNETIC WAVES

(71) Applicant: ELECTRONICS AND TELECOMMUNICATIONS RESEARCH INSTITUTE, Daejeon (KR)

(72) Inventors: Chang Hee HYOUNG, Daejeon (KR); Jong Hwa KWON, Daejeon (KR); Jung Hwan HWANG, Daejeon (KR)

(73) Assignee: ELECTRONICS AND TELECOMMUNICATIONS RESEARCH INSTITUTE, Daejeon (KR)

(21) Appl. No.: 19/056,129

(22) Filed: Feb. 18, 2025

(30) Foreign Application Priority Data
Aug. 6, 2024 (KR) 10-2024-0104867

(51) Int. Cl. H05K 9/00

(52) U.S. Cl. CPC H05K 9/0094; H05K 9/0005

(57) ABSTRACT

A semiconductor element according to embodiment of the inventive concept may include a first glass plate having a first surface and a second surface opposing the first surface, a metal frame surrounding an edge of the first glass plate, the metal frame being electrically connected to a ground line, a first transparent conductive layer provided on the first surface of the first glass plate, and a circuit block provided on the first surface of the first glass plate and spaced apart from the first transparent conductive layer. The first transparent conductive layer may have a lattice structure in which first unit lattices are arranged along one line, and an entire length of the one line may be about 0.25 times to about 0.50 times a wavelength λ of an electromagnetic wave to be blocked.

### CROSS-REFERENCE TO RELATED APPLICATIONS

This U.S. non-provisional patent application claims priority under 35 U.S.C. § 119 of Korean Patent Application No. 10-2024-0104867, filed on Aug. 6, 2024, the entire contents of which are hereby incorporated by reference.

### BACKGROUND

The present disclosure herein relates to a shielding structure for electromagnetic waves, and more particularly, to a shielding structure for electromagnetic waves, capable of protecting an electronic equipment or apparatus within a building against radioactive electromagnetic waves of a high-altitude electromagnetic pulse generated at high altitude.

The severity of damages caused by a high-altitude electromagnetic pulse (HEMP) that is a strong electromagnetic wave, generated due to a nuclear detonation or the like, has long been known. The electromagnetic wave, generated in a band of a few kHz to tens of MHz between nanoseconds and hundreds of nanoseconds after the generation of the high-altitude electromagnetic pulse, is known to have the highest electric field intensity and directly affect the ground surface and electronic equipment in a building, particularly, to damage sensitive electronic equipment such as semiconductors.

In order to effectively protect a facility against this strong electromagnetic wave, various electromagnetic wave shielding technologies are being proposed. Methods, for example, faraday cages, shielded rooms, and enclosures, or shielding materials or cables, have been proposed.

However, construction of shielding facilities and maintenance of these shielding facilities require large economic and time costs. Accordingly, technologies are required to effectively reduce the intensity of the high-altitude electromagnetic pulse entering non-shielding facilities from the outside to be within a range that the electronic equipment and the like in the facilities can endure.

### SUMMARY

The present disclosure provides a shielding structure for electromagnetic waves, capable of selectively blocking a high-altitude electromagnetic pulse.

The object of the present invention is not limited to the aforesaid, but other objects not described herein will be clearly understood by those skilled in the art from descriptions below.

An embodiment of the inventive concept provides a shielding structure for electromagnetic waves, the shielding structure including a first glass plate having a first surface and a second surface opposing the first surface, a metal frame surrounding an edge of the first glass plate, the metal frame being electrically connected to a ground line, a first transparent conductive layer provided on the first surface of the first glass plate, and a circuit block provided on the first surface of the first glass plate and spaced apart from the first transparent conductive layer. The first transparent conductive layer may have a lattice structure in which first unit lattices are arranged along one line, the first transparent conductive layer may be electrically connected to the ground line along the circuit block and the metal frame, and an entire length of the one line may be about 0.25 times to about 0.50 times a wavelength λ of an electromagnetic wave to be blocked.

In an embodiment of the inventive concept, a shielding structure for electromagnetic waves includes a first glass plate having a first surface and a second surface opposing the first surface, a second glass plate provided on the second surface of the first glass plate, the second glass plate having a third surface adjacent to the second surface and a fourth surface opposing the third surface, a metal frame surrounding edges of the first and second glass plates, a first transparent conductive layer provided on the first surface of the first glass plate, a second transparent conductive layer provided on the fourth surface of the second glass plate, and a circuit block provided on the fourth surface of the second glass plate and spaced apart from the second transparent conductive layer. The first transparent conductive layer may include a first area and a second area in contact with each other, and the first transparent conductive layer on the first area may have a lattice structure in which first unit lattices are connected to each other. The second transparent conductive layer may include a third area and a fourth area in contact with each other, and the second transparent conductive layer on the third area may have a lattice structure in which second unit lattices are connected to each other. A length of one side of each of the first and second unit lattices may be about 0.02 times to about 0.05 times a wavelength λ of an electromagnetic wave to be blocked.

In an embodiment of the inventive concept, a shielding structure for electromagnetic waves includes a substrate having a first surface and a second surface opposing each other, a first conductive layer provided on the first surface of the substrate, and a second conductive layer provided on the second surface of the substrate. The first conductive layer may have a lattice structure in which first unit lattices are connected to each other, and the second conductive layer may have a lattice structure in which second unit lattices are connected to each other. A width of each of the first and second unit lattices may be about 0.02 times to about 0.05 times a wavelength λ of an electromagnetic wave to be blocked.

### BRIEF DESCRIPTION OF THE FIGURES

The accompanying drawings are included to provide a further understanding of the inventive concept, and are incorporated in and constitute a part of this specification. The drawings illustrate embodiments of the inventive concept and, together with the description, serve to explain principles of the inventive concept. In the drawings:

FIG. 1 is a plan view illustrating a shielding structure for electromagnetic waves according to an embodiment of the inventive concept;

FIG. 2 is an enlarged view illustrating a shielding structure for electromagnetic waves according to an embodiment of the inventive concept, and is an enlarged view illustrating area A in FIG. 1;

FIG. 3 is a side cross-sectional view illustrating a shielding structure for electromagnetic waves according to an embodiment of the inventive concept;

FIGS. 4A and 4B are each a plan view illustrating a shielding structure for electromagnetic waves according to an embodiment of the inventive concept;

FIGS. 5A and 5B are each a schematic view illustrating a circuit model of a shielding structure for electromagnetic waves according to an embodiment of the inventive concept;

FIG. 6 is a plan view illustrating a shielding structure for electromagnetic waves according to an embodiment of the inventive concept; and

FIGS. 7A and 7B are each a schematic view illustrating a circuit model of a shielding structure for electromagnetic waves according to an embodiment of the inventive concept.

### DETAILED DESCRIPTION

The inventive concept will now be described more fully hereinafter with reference to the accompanying drawings, in which embodiments of the inventive concepts are shown. The inventive concept may, however, be embodied in various forms in different forms and should not be construed as limited to the embodiments set forth herein. Rather, these embodiments are provided so that this disclosure will be thorough and complete, and will fully convey the scope of the inventive concept to those skilled in the art.

The terms used herein is to describe embodiments only and is not intended to be limit the inventive concept. In this specification, the singular expressions “a”, “an” and “the” are intended to include the plural forms as well, unless the context clearly indicates otherwise. It will be further understood that the terms “comprises” and/or “comprising”, when used in this specification, specify the presence of stated components, steps, operations, and/or devices, but do not preclude the possibility of the presence or addition of one or more other components, steps, operations, and/or devices. Since preferred embodiments are provided below, the order of the reference numerals given in the description is not limited thereto.

Unless otherwise defined, all terms (including technical and scientific terms) used herein have the same meaning as commonly understood by one of ordinary skill in the art to which this invention belongs. Moreover, detailed descriptions related to well-known functions or configurations will be ruled out in order not to unnecessarily obscure subject matters of the present invention.

It will be understood that, although the terms “first”, “second”, etc. may be used herein to describe various regions, films (or layers), or the like, the regions and the films are not to be limited by these terms. These terms are only used to distinguish one region or film (or layer) from another region or film (or layer). Like reference numerals or symbols refer to like elements throughout. Unless otherwise defined, all terms used herein have the same meaning as commonly understood by one of ordinary skill in the art to which this invention belongs.

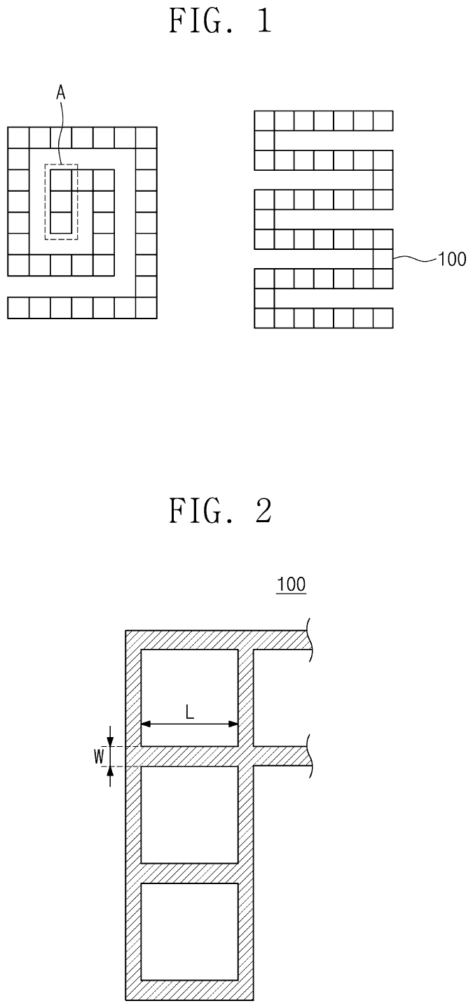

Hereinafter, a shielding structure for electromagnetic waves according to an embodiment of the inventive concept will be described with reference to the drawings. FIG. 1 is a plan view illustrating a shielding structure for electromagnetic waves according to an embodiment of the inventive concept, and illustrates a first conductive layer 100 constituting the shielding structure for electromagnetic waves. FIG. 2 is an enlarged view illustrating a shielding structure for electromagnetic waves according to an embodiment of the inventive concept, and is an enlarged view illustrating area A in FIG. 1.

Referring to FIGS. 1 and 2, a first conductive layer 100 may have a lattice structure. Specifically, the first conductive layer 100 may have a structure in which first unit lattices are arranged along one line. The first unit lattices may be in contact with other first unit lattices adjacent thereto. As an example, the first unit lattices connected to each other may have a ladder shape. However, this is just one example of a planar shape of the first unit lattices, and an embodiment of the inventive concept is not limited thereto. An entire length of the one line may be about 0.25 times to about 0.50 times a wavelength λ of an electromagnetic wave to be blocked by the shielding structure for electromagnetic waves. The shape of the line constituted by the first unit lattices may not be limited. For example, the line constituted by the first unit lattices may be a curve, and the first conductive layer 100 may have various structure such as a spiral structure or a meander line structure as in FIG. 1.

As used herein, a unit lattice may mean the smallest unit among repeating structures shown in the lattice structure. A planar shape of the unit lattice may be a square shape. However, an embodiment of the inventive concept is not limited thereto, and the planar shape of the unit lattice may be a rectangular or hexagonal shape. Hereinafter, for convenience of explanation, the unit lattice will be described on the assumption that the planar shape of the unit lattice is a square shape.

In other words, the first unit lattices may mean empty areas defined such that straight lines arranged at certain intervals and extending in one direction are perpendicularly intersect with straight lines arranged at certain intervals and extending in a direction perpendicular to the one direction. Here, a thickness W of each of the straight lines constituting the first unit lattices may be changed according to a frequency of an electromagnetic wave to be blocked by the shielding structure for electromagnetic waves. For example, as the frequency of the electromagnetic wave to be blocked increases, the thickness W of each of the straight lines may decrease.

A length L of one side of the first unit lattices of the first conductive layer 100 may determine a frequency band of the electromagnetic wave which may pass through the first conductive layer 100. The length L of the one side of the first unit lattices may be less than a wavelength of an electromagnetic wave to be blocked by the first conductive layer 100. For example, when the wavelength of the electromagnetic wave to be blocked is λ, the length L of the one side of the first unit lattices may be about 0.02 times to about 0.05 times λ. Here, a shielding effect for the electromagnetic wave having the wavelength λ may be at least about 20 dB.

A shielding effectiveness, SE (dB) for the electromagnetic wave by the first conductive layer 100 may be measured using Equation 1 below. L represents the length of the one side of each of the first unit lattices, λₐ represents the wavelength of the electromagnetic wave passing through the lattice structure, and n represents the number of the first unit lattices in λₐ/2. In a case in which the planar shape of the first unit lattices is a rectangle, L may represent a longer length among horizontal lengths and vertical lengths of the rectangle.

$$SE [ d B ] = K {log}_{10} ( \frac{{λ}_{a}}{2} L ) - 20 {log}_{10} n \qquad Equation 1$$

Here, a constant K may be changed according to the shape of the lattice structure. For example, in the unit lattice having a rectangular shape, K may be about 20.

The first conductive layer 100 may include a conductive material. The first conductive layer 100 may be transparent. In other words, visible light may pass through the first conductive layer 100. For example, the first conductive layer 100 may include at least one of indium tin oxide (ITO), metal nanowire, graphene, or a conductive polymer. However, an embodiment of the inventive concept is not limited thereto, and the first conductive layer 100 may not be transparent as necessary.

A size of each of the first unit lattices of the first conductive layer 100 may be changed in light of the shielding effectiveness, SE for the electromagnetic wave according to Equation 1, the size of the first conductive layer 100, and the frequency band of the electromagnetic wave to be blocked. As an example, a height of the first conductive layer 100 may be about 1.2 m to about 1.6 m, a width of the first conductive layer 100 may be about 0.9 m to about 1.2 m, and in a case in which the electromagnetic wave having a frequency of about 30 MHz is blocked, the length L of the one side of the first unit lattices of the first conductive layer 100 may be about 10 cm to about 20 cm. Here, a transmission loss of the first conductive layer 100 with respect to electromagnetic waves for communication in a few-GHz band may be near about 0. That is, the electromagnetic waves for communication may not be lost by the first conductive layer 100 but pass through the first conductive layer 100. Hereinafter, the electromagnetic wave to be blocked by the shielding structure for electromagnetic waves herein will be described on the assumption that the electromagnetic wave is an electromagnetic wave having a low frequency of about 30 MHz. Accordingly, the “electromagnetic wave to be blocked” and the “low-frequency electromagnetic wave” may have the same meaning and be interchangeably used. However, an embodiment of the inventive concept is not limited thereto, and the wavelength of the electromagnetic wave to be blocked by the shielding structure for electromagnetic waves may be changed as necessary.

The first conductive layer 100 may have shielding properties with respect to a frequency in a band of a few kHz to tens of MHz. In other words, the low-frequency electromagnetic wave in the band of a few kHz to tens of MHz may not pass through the first conductive layer 100. However, with respect to the electromagnetic waves for communication in the few-GHz band, a difference between the length L of the one side of the first unit lattices and the size of a wavelength of the electromagnetic waves for communication is not significant, and thus the transmission loss may be reduced. That is, the first conductive layer 100 may have a high transmission loss in a low-frequency band, and hardly have a transmission loss in a high-frequency band. Accordingly, the shielding structure for electromagnetic waves may be provided which selectively blocks a high-altitude EMP signal and does not affect the electromagnetic waves in the high-frequency band used for wireless communication.

In addition, according to an embodiment of the inventive concept, the size and the arrangement of the lattice structure of the first conductive layer 100 may be changed in light of the shielding effectiveness, SE for the electromagnetic wave according to Equation 1, the size of the first conductive layer 100, and the frequency band to be blocked. Thus, a shielding film for electromagnetic waves may be provided which is capable of being designed and adjusted to match various frequency bands.

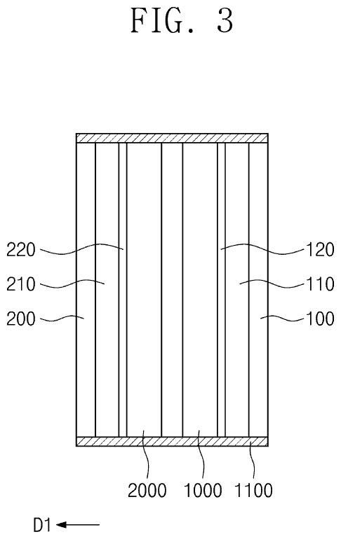

FIG. 3 is a side cross-sectional view of a shielding structure for electromagnetic waves according to an embodiment of the inventive concept. Referring to FIG. 3, a first glass plate 1000 may be provided. The first glass plate 1000 may have a first surface and a second surface opposing the first surface. A first substrate 110 and a first conductive layer 100 may be provided on the first surface of the first glass plate 1000. The first substrate 110 may be provided between the first glass plate 1000 and the first conductive layer 100. A thickness of the first substrate 110 may be about 1 μm to about 500 μm, but an embodiment of the inventive concept is not limited thereto. The first substrate 110 may include a material having a dielectric property. For example, the first substrate 110 may include a polymer film having an insulation property. The first substrate 110 may be attached onto the first glass plate 1000 by using a first adhesive layer 120. However, an embodiment of the inventive concept is not limited thereto. The shielding structure for electromagnetic waves may not include the first substrate 110 or the first adhesive layer 120. For example, the first conductive layer 100 may be in contact with the first surface of the first glass plate 1000. A size of the first conductive layer 100 may be the same as or smaller than a size of the first glass plate 1000. Although not illustrated, when necessary, a first protective layer may be provided on the first surface of the first glass plate 1000. The first protective layer may cover the first conductive layer 100 on the first surface of the first glass plate 1000.

A second glass plate 2000 may be provided on the second surface of the first glass plate 1000. The second glass plate 2000 may be spaced apart from the first glass plate 1000 in a first direction D1. As used herein, the first direction D1 may indicate a direction which is perpendicular to the first surface of the first glass plate 1000 and is from the first surface toward the second surface. The second glass plate 2000 may include a third surface adjacent to the second surface of the first glass plate 1000, and a fourth surface opposing the third surface. A second substrate 210 may be provided on the fourth surface of the second glass plate 2000. A thickness of the second substrate 210 may be about 1 μm to about 500 μm, but an embodiment of the inventive concept is not limited thereto. The second substrate 210 may include a material having a dielectric property. For example, the second substrate 210 may include a polymer film having an insulation property. The second substrate 210 may be attached onto the second glass plate 2000 by using a second adhesive layer 220. The material constituting the second substrate 210 may be the same as the material constituting the first substrate 110. A material constituting the second adhesive layer 220 may be the same as a material constituting the first adhesive layer 120. However, an embodiment of the inventive concept is not limited thereto.

A second conductive layer 200 may be provided on the second substrate 210. For example, a shape may be provided in which the second substrate 210 and the second conductive layer 200 may be stacked, in sequence, on the second glass plate 2000 along the first direction D1. A size of the second conductive layer 200 may be the same as or smaller than a size of the second glass plate 2000. However, an embodiment of the inventive concept is not limited thereto, and the shielding structure for electromagnetic waves may not include the second substrate 210 or the second adhesive layer 220. For example, the second conductive layer 200 may be in contact with the fourth surface of the second glass plate 2000.

The second conductive layer 200 may have a lattice structure in which second unit lattices are connected to each other. The second unit lattices may be in contact with other second unit lattices adjacent thereto. A planar shape of each of the of the second unit lattices of the second conductive layer 200 may be a square. However, an embodiment of the inventive concept is not limited thereto, and the second unit lattices may have various planar shapes such as rectangles or hexagons. Here, the second unit lattices of the second conductive layer 200 may mean empty areas defined such that straight lines arranged at certain intervals and extending in one direction perpendicularly intersect with straight lines arranged at certain intervals and extending in a direction perpendicular to the one direction.

A length of one side of each of the second unit lattices of the second conductive layer 200 may be smaller than a wavelength of an electromagnetic wave to be blocked by the second conductive layer 200. For example, when the wavelength of the electromagnetic wave to be blocked is λ, the length of the one side of the second unit lattices may be about 0.02 times to about 0.05 times λ. The length of the one side of the second unit lattices of the second conductive layer 200 may be the same as the length L of the one side of the first unit lattices of the first conductive layer 100. However, an embodiment of the inventive concept is not limited thereto.

The second conductive layer 200 may include a conductive material. The second conductive layer 200 may be transparent. In other words, visible light may pass through the second conductive layer 200. For example, the second conductive layer 200 may include at least one of indium tin oxide (ITO), metal nanowire, graphene, or a conductive polymer. However, an embodiment of the inventive concept is not limited thereto, and the second conductive layer 200 may not be transparent as necessary. The material constituting the second conductive layer 200 may be the same as the material constituting the first conductive layer 100. Although not illustrated, when necessary, a second protective layer may be provided on the fourth surface of the second glass plate 2000. The second protective layer may cover the second conductive layer 200 on the fourth surface of the second glass plate 2000.

A metal frame 1100 surrounding respective edges of the first glass plate 1000 and the second glass plate 2000 may be provided. Here, the edges of the first glass plate 1000 and the second glass plate 2000 may respectively indicate an outer area of the first glass plate 1000 extending along side surfaces, each of which connects the first surface and the second surface of the first glass plate 1000, and an outer area of the second glass plate 2000 extending along side surfaces, each of which connects the third surface and the fourth surface of the second glass plate 2000. In a plan view, the metal frame 1100 may have a closed loop shape extending along the edges of the first glass plate 1000 and the second glass plate 2000. The metal frame 1100 may include a material having conductivity. The first and second glass plates 1000 and 2000 and the metal frame 1100 may constitute a single window, and the metal frame 1100 may be electrically connected to a ground line in a building on which the window is installed. The metal frame 1100 may be arranged to be spaced apart from the first conductive layer 100 and the second conductive layer 200. For example, the first conductive layer 100 and the second conductive layer 200 may be disposed at central portions of the first glass plate 1000 and the second glass plate 2000, respectively.

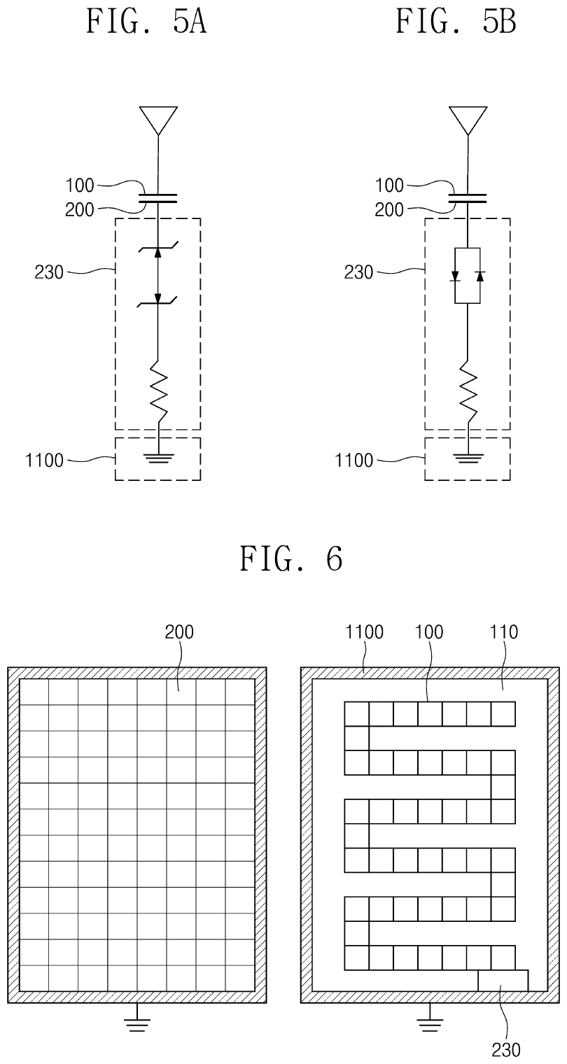

A circuit block 230 may be provided on the fourth surface of the second glass plate 2000. The circuit block 230 may be spaced apart from the second conductive layer 200. For example, the circuit block 230 may be provided in the form of a kind of sticker on the second conductive layer 200. The circuit block 230 may be electrically connected to the second conductive layer 200. The circuit block 230 may be provided in an area on the second glass plate 2000, which is adjacent to the metal frame 1100. The circuit block 230 may be a semiconductor element including at least one diode and at least one resistor. The configuration of the circuit block 230 and a role according to the configuration will be described in more detail with reference to FIGS. 5A and 5B.

FIG. 3 illustrates the first conductive layer 100 and the second conductive layer 200 which are provided to the first and second glass plates 1000 and 2000, respectively, but an embodiment of the inventive concept is not limited thereto. A third plate or substrate may be provided in which the first conductive layer 100 and the second conductive layer 200 are respectively disposed on opposite surfaces of a single substrate. For example, the first conductive layer 100 may be attached to a top surface of the substrate, and the second conductive layer 200 may be attached to a bottom surface opposing the top surface of the substrate. Here, the substrate may be transparent. The third plate or substrate may be attached onto any one surface of the first glass plate 1000 or the second glass plate 2000. Alternatively, the third plate or substrate may be provided to each of the first glass plate 1000 and the second glass plate 2000. For example, the third plate or substrate may be provided to each of the first surface of the first glass plate 1000 and the fourth surface of the second glass plate 2000. In addition, the third plate or substrate may be attached to an outer wall or an inner wall of the building, not to the glass plate. The following will be described based on an embodiment in FIG. 3.

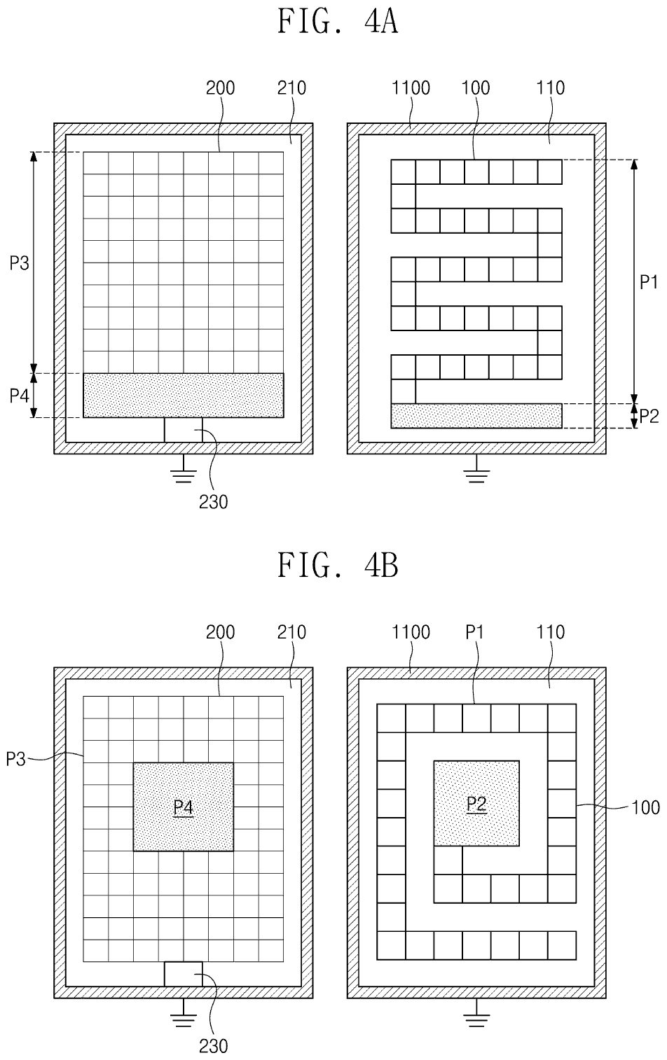

FIGS. 4A and 4B are each a plan view illustrating a shielding structure for electromagnetic waves according to an embodiment of the inventive concept, and side cross-sectional views of FIGS. 4A and 4B may correspond to FIG. 3. For convenience of explanation, FIGS. 4A and 4B each illustrate a plan view of the shielding structure for electromagnetic waves in the first direction D1 and a plan view of the shielding structure for electromagnetic waves in a direction opposite to the first direction D1. Referring to FIG. 4A, a first conductive layer 100 may be provided on a first substrate 110. The first conductive layer 100 may be substantially similar to that described with reference to FIG. 1.

However, unlike FIG. 1, the first conductive layer 100 may include a first area P1 and a second area P2 which are in contact with each other. The first conductive layer 100 on the first area P1 may have a lattice structure in which first unit lattices are connected to each other. The first conductive layer 100 on the second area P2 may not have the lattice structure. A planar shape of the first conductive layer 100 on the second area P2 may be a solid plate shape or a solid thin film shape.

The first conductive layer 100 on the first area P1 may have a structure in which the first unit lattices are arranged along one line. The first unit lattices may be in contact with other first unit lattices adjacent thereto. As an example, the first unit lattices connected to each other may have a ladder shape. However, this is just one example of a planar shape of the first unit lattices, and an embodiment of the inventive concept is not limited thereto. Here, the first unit lattices may mean empty areas defined such that straight lines arranged at certain intervals and extending in one direction perpendicularly intersect with straight lines arranged at certain intervals and extending in a direction perpendicular to the one direction. The first conductive layer 100 on the second area P2 may have the same structure as one in which some of the empty areas are filled with the same material as a material constituting the first conductive layer 100. In the first conductive layer 100 on the second area P2, as the material constituting the first conductive layer 100 is the same as the material constituting the empty areas, the lattice structure in which the first unit lattices are divided may be invisible. That is, the first conductive layer 100 on the second area P2 may be the same as one in which at least one of the first unit lattices is filled. The first area P1 may mean a remaining portion except for the second area P2 of the first conductive layer 100. A size and an arrangement of the second area P2 may be changed as necessary.

A second conductive layer 200 may be provided on a second substrate 210. The second conductive layer 200 may be substantially similar to that described with reference to FIG. 3. However, unlike FIG. 3, the second conductive layer 200 may include a third area P3 and a fourth area P4 which are in contact with each other. The second conductive layer 200 on the third area P3 may have a lattice structure in which second unit lattices are connected to each other. The second unit lattices may be in contact with other second unit lattices adjacent thereto. The second unit lattices may mean empty areas defined such that straight lines arranged at certain intervals and extending in one direction perpendicularly intersect with straight lines arranged at certain intervals and extending in a direction perpendicular to the one direction. The second conductive layer 200 on the fourth area P4 may not have the lattice structure. A solid planar shape of the second conductive layer 200 on the fourth area P4 may be a solid plate shape or a thin film shape.

The second conductive layer 200 on the fourth area P4 may have the same structure as one in which some of the empty areas are filled with the same material as a material constituting the second conductive layer 200. In the second conductive layer 200 on the fourth area P4, as the material constituting the second conductive layer 200 is the same as the material constituting the empty areas, the lattice structure in which the second unit lattices are divided may be invisible. That is, the second conductive layer 200 on the fourth area P4 may be the same as one in which at least one of the second unit lattices is filled. The third area P3 may mean a remaining portion except for the fourth area P4 of the second conductive layer 200. A size and an arrangement of the fourth area P4 may be changed as necessary. In a plan view, at least a portion of the fourth area P4 may overlap at least a portion of the second area P2. The size of the fourth area P4 may be the same as or larger than the size of the second area P2.

FIG. 4A illustrates the fourth area P4 which is in contact with one side surface of the fourth area P4 or the third area P3 of the second conductive layer 200, but an embodiment of the inventive concept is not limited thereto. The respective sizes and arrangements of the first to fourth areas P1, P2, P3 and P4 may be changed as necessary. For example, referring to FIG. 4B, the second area P2 of the first conductive layer 100 may be disposed at a central portion of the first conductive layer 100. The first conductive layer 100 on the first area P1 may have a spiral lattice structure extending from the first conductive layer 100 on the second area P2. The fourth area P4 of the second conductive layer 200 may be disposed at a central portion of the second conductive layer 200. In a plan view, the third area P3 of the second conductive layer 200 may be in contact with the fourth area P4 and surround an edge of the fourth area P4. The third area P3 may mean a remaining portion except for the fourth area P4 of the second conductive layer 200. In a plan view, at least a portion of the second area P2 may overlap at least a portion of the fourth area P4.

FIGS. 5A and 5B are each a schematic view illustrating a circuit model of a shielding structure for electromagnetic waves according to an embodiment of the inventive concept, and illustrate the circuit model of the shielding structure for electromagnetic waves described with reference to FIGS. 4A and 4B. Referring to FIGS. 5A and 5B, a first conductive layer 100 and a second conductive layer 200 may absorb a low-frequency electromagnetic wave. More specifically, the first conductive layer 100 may obtain the low-frequency electromagnetic wave introduced from the outside into a building on which the first conductive layer 100 is installed. This may be indicated as an antenna in the circuit model. The low-frequency electromagnetic wave obtained by the first conductive layer 100 may be transmitted to the second conductive layer 200. The first conductive layer 100 and the second conductive layer 200 may be indicated as a capacitor in the circuit model. A circuit block 230 connected to the second conductive layer 200 may be indicated as a diode bridge and a resistor. A metal frame 1100 connected to a ground line of the building may be indicated as ground in the circuit model. That is, the circuit model shows a process in which the low-frequency electromagnetic wave introduced through the first conductive layer 100 is grounded by being transmitted along the second conductive layer 200, the circuit block 230, and the metal frame 1100 in sequence.

Hereinafter, operational principles of a shielding structure for electromagnetic waves according to an embodiment of the inventive concept will be described in more detail. a first conductive layer 100 may selectively obtain a low-frequency electromagnetic wave. For example, when a very large amount of energy is generated from the outside of the building by a high-altitude electromagnetic pulse (HEMP), the low-frequency electromagnetic wave having very high electric field intensity may be introduced into the first conductive layer 100. The low-frequency electromagnetic wave may be transmitted to a second conductive layer 200. In a plan view, as a second area P2 of the first conductive layer 100 and a fourth area P4 of the second conductive layer 200 overlap each other, the first conductive layer 100 and the second conductive layer 200 may achieve capacitive coupling. As the low-frequency electromagnetic wave is transmitted to the second conductive layer 200 by the capacitive coupling, the second conductive layer 200 may have a high potential. A circuit block 230 may be driven by the high potential of the second conductive layer 200. In the present disclosure, when the circuit block 230 is driven, it may mean a state in which current flows into the circuit block 230, an electric signal (electromagnetic wave) received by the circuit block 230 may be transmitted to the outside of the circuit block 230. The circuit block 230 may be driven by an electromagnetic wave having a voltage higher than a threshold voltage, and here, the circuit block 230 may electrically connect the second conductive layer 200 to a metal frame 1100. In other words, the circuit block 230 may transmit the electric signal (electromagnetic wave), having a magnitude equal to or greater than the threshold voltage of the circuit block 230, from the second conductive layer 200 to the metal frame 1100. That is, the electromagnetic wave induced in the first conductive layer 100 may be transmitted to the ground line through the second conductive layer 200, the circuit block 230, and the metal frame 1100. The threshold voltage may be about 3 V to about 100 V. However, an embodiment of the inventive concept is not limited thereto, and the threshold voltage of the circuit block 230 may be changed as necessary.

The circuit block 230 may include at least one diode. For example, the circuit block 230 may include two diodes connected to each other in series or in parallel. The two diodes may constitute a forward bridge or reverse bridge structure to limit a voltage input to the circuit block 230. For example, as in FIG. 5A, the diodes inside the circuit block 230 may include at least one zener diode. A size of an alternate current signal may be limited by a reverse arrangement of a zener diode bridge having a high withstand voltage. However, an embodiment of the inventive concept is not limited thereto, and the type and the arrangement of the diodes may be changed as necessary. For example, the diodes may be configured as in FIG. 5B. Alternatively, the diodes may include at least one light emitting element LED. In addition, FIGS. 5A and 5B illustrate a bridge structure constituted by the two diodes, but the circuit block 230 may include several diodes connected to each other in series. A portion of the low-frequency electromagnetic wave transmitted through the diodes of the circuit block 230 may be consumed as thermal energy through a resistor in the circuit block 230. A remaining portion of the low-frequency electromagnetic wave transmitted through the diodes may be transmitted along the circuit block 230 to the metal frame 1100. The low-frequency electromagnetic wave of the remaining portion transmitted to the metal frame 1100 may be transmitted along the ground line and grounded.

The size of the threshold voltage of the circuit block 230 may be changed as necessary. For example, the circuit block 230 may be driven only when receiving an electric signal (electromagnetic wave) having high electric field intensity. Accordingly, the shielding structure for electromagnetic waves may be provided in which the low-frequency electromagnetic wave having low electric field intensity used for communication is not affected by the shielding structure for electromagnetic waves.

FIG. 6 is a plan view illustrating a shielding structure for electromagnetic waves according to an embodiment of the inventive concept. For convenience of explanation, FIG. 6 illustrates a plan view of the shielding structure for electromagnetic waves in the first direction D1 and a plan view of the shielding structure for electromagnetic waves in a direction opposite to the first direction D1. The configuration of the shielding structure for electromagnetic waves according to an embodiment in FIG. 6 may be similar as that described with reference to FIG. 3. For example, although not illustrated, a first substrate 110 and a first conductive layer 100 may be provided on a first glass plate 1000, and a second substrate 210 and a second conductive layer 200 may be provided on a second glass plate 2000. A metal frame 1100 surrounding an edge of each of the first glass plate 1000 and the second glass plate 2000 may be provided.

The first conductive layer 100 may be substantially the same to that described with reference to FIG. 1. For example, the conductive layer 100 may have a structure in which first unit lattices are arranged along one line. An entire length of the one line may be about 0.25 to about 0.50 times a wavelength λ of an electromagnetic wave to be blocked by the shielding structure for electromagnetic waves.

The second conductive layer 200 may be substantially similar to that described with reference to FIG. 3. The second conductive layer 200 in FIG. 6 may have a lattice structure in an entire area of the second conductive layer 200. For example, the second conductive layer 200 may have a lattice structure in which second unit lattices are connected to each other. The second unit lattices of the second conductive layer 200 may mean empty areas defined such that straight lines arranged at certain intervals and extending in one direction perpendicularly intersect with straight lines arranged at certain intervals and extending in a direction perpendicular to the one direction. Here, both ends of each of the straight lines constituting the second unit lattices may be connected to the metal frame 1100. In other words, an edge of the second conductive layer 200 may be in contact with the metal frame 1100.

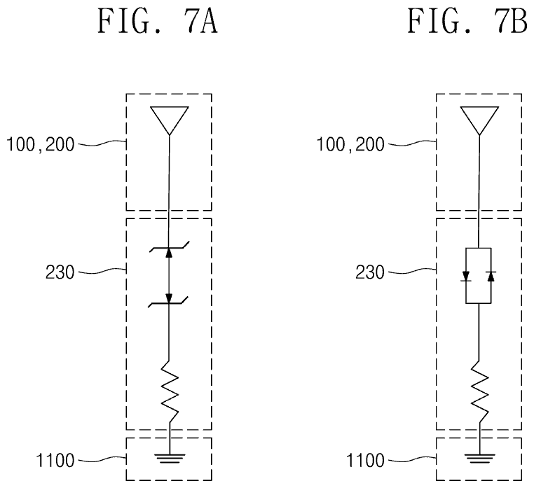

A circuit block 230 may be provided on a first surface of the first glass plate 1000. The circuit block 230 may be spaced apart from the first conductive layer 100. The circuit block 230 may be substantially the same as that described with reference to FIGS. 3 to 5B. For example, the circuit block 230 may be driven by an electromagnetic wave having a voltage higher than a threshold voltage of the circuit block 230. Here, the circuit block 230 may electrically connect the first conductive layer 100 to the metal frame 1100. Operational principles of the shielding structure for electromagnetic waves according to an embodiment in FIG. 6 will be described in more detail with reference to FIGS. 7A and 7B.

FIGS. 7A and 7B are each a schematic view illustrating a circuit model of a shielding structure for electromagnetic waves according to an embodiment of the inventive concept, and illustrate the circuit model of the shielding structure for electromagnetic waves described with reference to FIG. 6. A first conductive layer 100 and a second conductive layer 200 may serve to absorb a low-frequency electromagnetic wave. This may be indicated as an antenna in the circuit model. More specifically, the first conductive layer 100 may obtain the low-frequency electromagnetic wave introduced from the outside into a building on which the first conductive layer 100 is installed. A circuit block 230 connected to the first conductive layer 100 may be indicated as a diode bridge and a resistor. A metal frame 1100 connected to a ground line of the building may be indicated as ground in the circuit model. That is, the circuit model shows a process in which the low-frequency electromagnetic wave introduced through the first conductive layer 100 and the second conductive layer 200 is transmitted to the ground line along the circuit block 230 and the metal frame 1100 in sequence.

The low-frequency electromagnetic wave having very high electric field intensity may be introduced into the first conductive layer 100. The first conductive layer 100 may obtain at least a portion of the low-frequency electromagnetic wave and have a high potential. The circuit block 230 may be driven by the high potential of the first conductive layer 100. Here, the circuit block 230 may electrically connect the first conductive layer 100 to the metal frame 1100. In other words, the circuit block 230 may transmit an electromagnetic wave, having a voltage equal to or greater than a threshold voltage of the circuit block 230, from the first conductive layer 100 to the metal frame 1100. For example, the threshold voltage of the circuit block 230 may be about 3 V to about 100 V. However, an embodiment of the inventive concept is not limited thereto, and the threshold voltage of the circuit block 230 may be changed as necessary.

The circuit block 230 may be substantially the same as or similar to that described with reference to FIGS. 5A and 5B. For example, the circuit block 230 may include two diodes connected to each other in series or in parallel. The diodes inside the circuit block 230 may include at least one zener diode as in FIG. 7A, or may not include the zener diode as in FIG. 7B. Although FIGS. 7A and 7B illustrate a bridge structure constituted by the two diodes, the circuit block 230 may include several diodes connected to each other in series, and the configuration and the arrangement of the diodes may be changed as necessary. A portion of the low-frequency electromagnetic wave transmitted through the diodes of the circuit block 230 may be consumed as thermal energy through a resistor in the circuit block 230. A remaining portion of the low-frequency electromagnetic wave transmitted through the diodes may be transmitted along the circuit block 230 to the metal frame 1100. The low-frequency electromagnetic wave of the remaining portion transmitted to the metal frame 1100 may be transmitted along the ground line and grounded.

The second conductive layer 200 may obtain a remaining portion of the low-frequency electromagnetic wave, which is not obtained through the first conductive layer 100. The low-frequency electromagnetic wave of the remaining portion transmitted to the first conductive layer 100 may be transmitted along the second conductive layer 200, the metal frame 1100, and the ground line. Accordingly, the low-frequency electromagnetic wave of the remaining portion transmitted to the first conductive layer 100 may be prevented from being introduced into an interior.

The shielding structure for electromagnetic waves according to the embodiment of the inventive concept may include the conductive thin film having the lattice structure, thereby providing the shielding structure for electromagnetic waves capable of selectively blocking the high-altitude electromagnetic pulse.

The shielding structure for electromagnetic waves according to the embodiment of the inventive concept may include the conductive thin film having the lattice structure and the ground path connected to the conductive thin film, thereby providing the shielding structure for electromagnetic waves capable of effectively reducing the intensity of the high-altitude electromagnetic pulse having the high electric field intensity.

What is claimed is:

1. A shielding structure for electromagnetic waves, comprising:
a first glass plate having a first surface and a second surface opposing the first surface;
a metal frame surrounding an edge of the first glass plate, the metal frame being electrically connected to a ground line;
a first transparent conductive layer provided on the first surface of the first glass plate; and
a circuit block provided on the first surface of the first glass plate and spaced apart from the first transparent conductive layer,
wherein the first transparent conductive layer has a lattice structure in which first unit lattices are arranged along one line, and
the first transparent conductive layer is electrically connected to the ground line along the circuit block and the metal frame,
wherein an entire length of the one line is about 0.25 times to about 0.50 times a wavelength λ of an electromagnetic wave to be blocked.

2. The shielding structure for electromagnetic waves of claim 1, wherein a planar shape of the first unit lattices is a square shape, and
a length of one side of each of the first unit lattices is about 0.02 times to about 0.05 times the wavelength λ.

3. The shielding structure for electromagnetic waves of claim 1, further comprising a transparent substrate provided between the first glass plate and the first transparent conductive layer,
wherein the first transparent conductive layer is attached onto a top surface of the transparent substrate, and
the transparent substrate comprises a material having a dielectric property.

4. The shielding structure for electromagnetic waves of claim 3, wherein the transparent substrate is attached onto the first surface of the first glass plate by using an adhesive layer.

5. The shielding structure for electromagnetic waves of claim 3, further comprising a second transparent conductive layer provided on a bottom surface of the transparent substrate,
wherein the second transparent conductive layer is provided between the bottom surface of the transparent substrate and the first surface of the first glass plate, and
the second transparent conductive layer has a lattice structure in which second unit lattices are connected to each other,
wherein a planar shape of the second unit lattices is a square shape, and
a length of one side of each of the second unit lattices is about 0.02 times to about 0.05 times the wavelength λ.

6. The shielding structure for electromagnetic waves of claim 1, further comprising:
a second glass plate provided on the second surface of the first glass plate; and
a third transparent conductive layer provided on the second glass plate,
wherein the first glass plate and the second glass plate are spaced apart from each other, and
the third transparent conductive layer has a lattice structure in which third unit lattices are connected to each other,
wherein a planar shape of the third unit lattices is a square shape, and
a length of one side of each of the third unit lattices is about 0.02 times to about 0.05 times the wavelength λ.

7. The shielding structure for electromagnetic waves of claim 1, wherein the circuit block transmits an electromagnetic wave, having a magnitude equal to or greater than a threshold voltage, from the first transparent conductive layer to the metal frame,
wherein the threshold voltage of the circuit block is about 3 V to about 100 V.

8. A shielding structure for electromagnetic waves, comprising:
a first glass plate having a first surface and a second surface opposing the first surface;
a second glass plate provided on the second surface of the first glass plate, the second glass plate having a third surface adjacent to the second surface and a fourth surface opposing the third surface;
a metal frame surrounding edges of the first and second glass plates;
a first transparent conductive layer provided on the first surface of the first glass plate;
a second transparent conductive layer provided on the fourth surface of the second glass plate; and
a circuit block provided on the fourth surface of the second glass plate and spaced apart from the second transparent conductive layer,
wherein the first transparent conductive layer comprises a first area and a second area in contact with each other, wherein the first transparent conductive layer on the first area has a lattice structure in which first unit lattices are connected to each other,
wherein the second transparent conductive layer comprises a third area and a fourth area in contact with each other, wherein the second transparent conductive layer on the third area has a lattice structure in which second unit lattices are connected to each other,
wherein a length of one side of each of the first and second unit lattices is about 0.02 times to about 0.05 times a wavelength λ of an electromagnetic wave to be blocked.

9. The shielding structure for electromagnetic waves of claim 8, wherein the first transparent conductive layer on the second area has a solid plate shape,
the second transparent conductive layer on the fourth area has a solid plate shape, and
in a plan view, at least a portion of the second area overlaps at least a portion of the fourth area.

10. The shielding structure for electromagnetic waves of claim 8, wherein the first transparent conductive layer and the second transparent conductive layer achieve capacitive coupling, and
the metal frame is electrically connected to a ground line,
wherein an electromagnetic wave induced in the first transparent conductive layer is transmitted to the ground line through the second transparent conductive layer, the circuit block, and the metal frame.

11. The shielding structure for electromagnetic waves of claim 8, wherein, in the first area of the first transparent conductive layer, the first unit lattices are continuously arranged along one line, and
an entire length of the one line is about 0.25 times to about 0.50 times a wavelength λ of an electromagnetic wave to be blocked.

12. The shielding structure for electromagnetic waves of claim 8, further comprising a protective layer provided on the first surface of the first glass plate and configured to cover the first transparent conductive layer.

13. The shielding structure for electromagnetic waves of claim 8, further comprising a first transparent substrate provided on the first glass plate, and a second transparent substrate provided on the second glass plate,
wherein the first transparent substrate is provided between the first glass plate and the first transparent conductive layer, and
the second transparent substrate is provided between the second glass plate and the second transparent conductive layer.

14. A shielding structure for electromagnetic waves, comprising:
a substrate having a first surface and a second surface opposing each other;
a first conductive layer provided on the first surface of the substrate; and
a second conductive layer provided on the second surface of the substrate,
wherein the first conductive layer has a lattice structure in which first unit lattices are connected to each other, and
the second conductive layer has a lattice structure in which second unit lattices are connected to each other,
wherein a width of each of the first and second unit lattices is about 0.02 times to about 0.05 times a wavelength 2 of an electromagnetic wave to be blocked.

15. The shielding structure for electromagnetic waves of claim 14, wherein visible light passes through the substrate, the first conductive layer, and the second conductive layer.

16. The shielding structure for electromagnetic waves of claim 14, wherein a thickness of the substrate is about 1 μm to about 500 μm.

17. The shielding structure for electromagnetic waves of claim 14, wherein the first unit lattices are arranged along one curve on the substrate,
wherein an entire length of the curve is about 0.25 times to about 0.50 times a wavelength λ of an electromagnetic wave to be blocked.
